(19) United States
(12) Patent Application Publication
(10) Pub. No.: US 2024/0339485 A1
(43) Pub. Date: Oct. 10, 2024

(54) INTEGRATED STRUCTURE OF OPTOELECTRONIC ELEMENT AND CIRCUIT, AND INTEGRATING METHOD THEREOF

(71) Applicant: Taiwan-Asia Semiconductor Corporation, Hsinchu City (TW)

(72) Inventors: Di-Bao WANG, Hsinchu City (TW); Chuan-Wei CHEN, Hsinchu City (TW)

(21) Appl. No.: 18/631,344

(22) Filed: Apr. 10, 2024

(30) Foreign Application Priority Data
Apr. 10, 2023 (TW) 112113371

(51) Int. Cl. H01L 27/146

(52) U.S. Cl. CPC H01L 27/14687; H01L 27/14623; H01L 27/14632; H01L 27/14636; H01L 27/14685

(57) ABSTRACT

The present invention provides an integrating method for optoelectronic elements and circuits, including: providing a silicon wafer including a plurality of circuit structures; providing a plurality of optoelectronic element dies, and each optoelectronic element die including a substrate and an optoelectronic element structure; performing a die-to-wafer bonding process so that one optoelectronic element die is correspondingly bonded to one circuit structure of the silicon wafer through the optoelectronic element structure; performing a compression over-molding process to encapsulate the optoelectronic element dies and a surface of the silicon wafer by a molding material; performing a grinding and polishing process to remove an unnecessary portion of the molding material and an unnecessary portion of the substrate of each optoelectronic element die; and performing a dicing process to form a plurality of integrated structures with the optoelectronic elements and the circuits.

### CROSS-REFERENCES TO RELATED APPLICATIONS

This application claims priority to Taiwan Patent Application No. 112113371 filed on Apr. 10, 2023, which is hereby incorporated by reference in its entirety.

### BACKGROUND OF THE INVENTION

### Field of the Invention

The present invention relates to a semiconductor device integration technology, particularly an integrated structure and integrating method of optoelectronic elements and circuits.

### Descriptions of the Related Art

Currently, the technology for manufacturing visible light sensing devices (such as CMOS image sensors) using silicon wafers is quite mature. These sensing devices basically integrate high-resolution pixels of sensing array elements and related reading/processing circuits. However, constrained by the quantum energy levels of silicon materials, traditional silicon infrared sensors can only be applicable to light emitting sources with wavelengths of about 940 nm. Their QE values are relatively low and cannot effectively meet sensing requirements with wavelengths greater than 1 μm.

Non-silicon-based materials (e.g., indium gallium arsenide) have lower energy levels than silicon, so they are more suitable for long-wavelength infrared rays with wavelengths greater than 1 μm. By adjusting the composition ratio of the three elements, the wavelength range for detection can be changed. However, manufacturing infrared sensing array elements with non-silicon-based materials requires complex integration technology of sensing pixels and reading/processing circuits. For example, in conventional practice, after the sensing array elements are bonded to the circuits, a grinding and thinning process needs to be performed directly on the sensing array elements. However, this method is prone to causing damage between the sensing array elements and the circuit interfaces, thereby reducing the yield and reliability of the device manufacturing.

Therefore, it is worthwhile to study how to design the integration technology of optoelectronic elements and circuits that can solve the aforementioned problems.

### SUMMARY OF THE INVENTION

The objective of the present invention is to provide an integrating method of optoelectronic elements and circuits.

To achieve the above objective, the present invention provides an integrating method of optoelectronic elements and circuits, including: providing a silicon wafer, the silicon wafer including a plurality of circuit structures; providing a plurality of optoelectronic element dies optoelectronic element dies including a substrate and an optoelectronic element structure; performing a die-to-wafer bonding process such that the optoelectronic element dies are stacked on a surface of the silicon wafer, wherein one of the optoelectronic element dies is correspondingly bonded to one of the circuit structures through the optoelectronic element structure; performing a compression over-molding process to encapsulate the optoelectronic device dies and the surface of the silicon wafer with a molding material; performing a grinding and polishing process to remove an unnecessary portion of the molding material and an unnecessary portion of the substrate of the optoelectronic element dies and expose the substrate of each of the optoelectronic element dies on a top surface after grinding and polishing; and performing a dicing process to form a plurality of integrated structures with the optoelectronic elements and the circuits.

In an embodiment of the present invention, in the step of performing the compression over-molding process, a thickness of the molding material is greater than a thickness of each of the optoelectronic element dies.

In an embodiment of the present invention, in the step of performing the grinding and polishing process, a remaining thickness of the substrate of each of the optoelectronic element dies is between 80 μm and 250 μm.

In an embodiment of the present invention, the molding material comprises epoxy resin, phenolic resin or melamine resin.

In an embodiment of the present invention, the substrate of each of the optoelectronic element dies is made of an III-V group semiconductor material.

In an embodiment of the present invention, the III-V group semiconductor material comprises indium phosphide or gallium antimonide.

In an embodiment of the present invention, the integrating method further includes the following steps: forming a plurality of micro-optical structures on the top surface after grinding and polishing, wherein each of the micro-optical structures is correspondingly disposed on the exposed substrate of each of the optoelectronic element dies.

In an embodiment of the present invention, the integrating method further includes the following steps: forming an anti-reflective coating on the top surface after grinding and polishing and on the micro-optical structures.

In an embodiment of the present invention, the anti-reflective coating includes zinc sulfide, zinc selenide or germanium.

In an embodiment of the present invention, the step of providing the optoelectronic element dies further includes the following steps: providing a composite semiconductor wafer; and dicing the composite semiconductor wafer into the optoelectronic element dies.

In an embodiment of the present invention, each of the circuit structures is a sensing circuit or a control circuit.

In an embodiment of the present invention, each of the circuit structures comprises a plurality of first electrical contacts exposed on the surface of the silicon wafer, and each of the optoelectronic element structures comprises a plurality of second electrical contacts exposed on a surface of the optoelectronic element structure; and in the die-to-wafer bonding process the optoelectronic element dies is correspondingly connected to the first electrical contacts of each of the circuit structures through the second electrical contacts of the optoelectronic element structure.

The present invention also includes an integrated structure of an optoelectronic element(s) and a circuit(s) using the integrating method above.

Accordingly, the integrating method of optoelectronic elements and circuits of the present invention uses a die-to-wafer bonding process to bond each optoelectronic element die and each circuit structure of the silicon wafer. Subsequently, the compression over-molding process is employed to encapsulate each optoelectronic element die and the surface of the silicon wafer with a molding material. The molding material can provide a stabilizing effect between each optoelectronic element die and the silicon wafer, thereby reducing the possibility of damage between each optoelectronic element die and each circuit structure interface during the subsequent grinding and polishing process so as to improve the yield of the product process and reduce manufacturing costs.

### BRIEF DESCRIPTION OF THE DRAWINGS

FIG. 1 is a flowchart of the integrating method of optoelectronic elements and circuits of the present invention.

FIG. 2 is a schematic view of a silicon wafer provided in the integrating method of optoelectronic elements and circuits of the present invention.

FIG. 3 is a schematic view of an optoelectronic element die provided in the integrating method of optoelectronic elements and circuits of the present invention.

FIG. 4 is a detailed flowchart of step S2 in the integrating method of optoelectronic elements and circuits of the present invention.

FIG. 5 is a schematic view of performing step S2 in the integrating method of optoelectronic elements and circuits of the present invention.

FIG. 6 is a schematic view of performing step S3 in the integrating method of optoelectronic elements and circuits of the present invention.

FIG. 7 is a schematic view of performing step S4 in the integrating method of optoelectronic elements and circuits of the present invention.

FIG. 8 is a schematic view of performing step S5 in the integrating method of optoelectronic elements and circuits of the present invention.

FIG. 9 is a schematic view of the integrated structure of an optoelectronic element and a circuit of the present invention.

FIG. 10 is another flowchart of the integrating method of optoelectronic elements and circuits of the present invention.

FIG. 11 is a schematic view of performing steps S51 and S52 in the integrating method of optoelectronic elements and circuits of the present invention.

FIG. 12 is another schematic view of the integrated structure of an optoelectronic element and a circuit of the present invention.

### DETAILED DESCRIPTION OF THE PREFERRED EMBODIMENT

Since the various aspects and embodiments are merely illustrative and not restrictive, after reading this specification, a person having ordinary skill in the art may also have other aspects and embodiments without departing from the scope of the present invention. The features and advantages of these embodiments and the scope of the patent application will be better appreciated from the following detailed description.

Herein, “a” or “an” is used to describe one or more devices and components described herein. Such a descriptive term is merely for the convenience of illustration and to provide a general sense of the scope of the present invention. Therefore, unless expressly stated otherwise, the term “a” or “an” is to be understood to include one or at least one, and the singular form also includes the plural form.

Herein, the terms “first” or “second” and similar ordinal numbers are mainly used to distinguish or refer to the same or similar devices or structures, and do not necessarily imply the spatial or temporal order of such devices or structures. It should be understood that in certain situations or configurations, ordinal numbers may be used interchangeably without affecting the practice of the present invention.

As used herein, the term “comprise” “include,” “have” or any other similar term is not intended to exclude additional, unrecited elements. For example, a device or structure comprising/including/having a plurality of elements is not solely limited to the elements listed herein but may comprise/include/have other elements not explicitly listed but generally inherent to the device or structure.

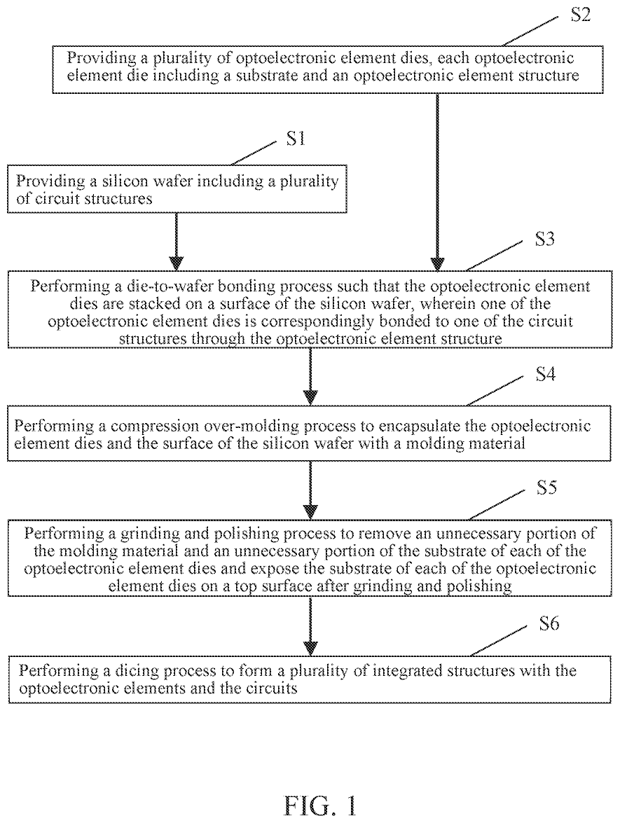

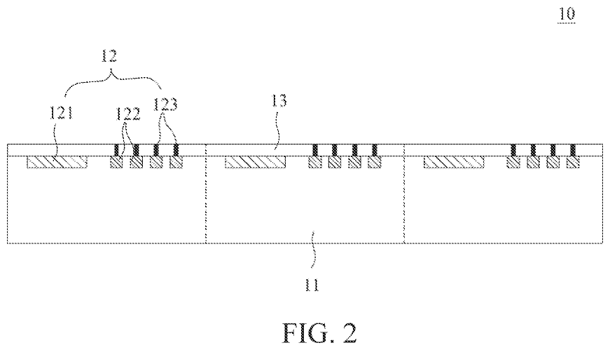

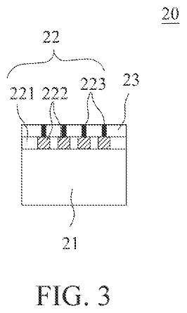

The integrating method of optoelectronic elements and circuits of the present invention is mainly used to integrate optoelectronic element dies and silicon wafers with pre-disposed circuit structures to produce integrated structures (e.g., integrated chips) with optoelectronic elements and corresponding circuits. Please refer to FIGS. 1 to 3 together. FIG. 1 is a flowchart of the integrating method of optoelectronic elements and circuits of the present invention. FIG. 2 is a schematic view of a silicon wafer provided in the integrating method of optoelectronic elements and circuits of the present invention. FIG. 3 is a schematic view of an optoelectronic element die provided in the integrating method of optoelectronic elements and circuits of the present invention. As shown in FIG. 1, the integrating method of optoelectronic elements and circuits of the present invention includes the following steps.

Step S1: providing a silicon wafer, the silicon wafer including a plurality of circuit structures.

As shown in FIGS. 1 and 2, firstly, the present invention provides a silicon wafer 10 as the basic structure for the integrated structure of an optoelectronic element(s) and a circuit(s) of the present invention. The silicon wafer 10 includes a first substrate 11 and a plurality of circuit structures 12. The first substrate 10 is made of a silicon material, and the plurality of circuit structures 12 are disposed on the first substrate 11. In an embodiment of the present invention, each circuit structure 12 may be a sensing circuit or a control circuit. Moreover, each circuit structure 12 may include a processing/interface circuit 121 and a plurality of pixel readout circuits 122. The processing/interface circuit 121 and the pixel reading circuits 122 are electrically connected to each other.

In addition, in the structure design, a first passivation layer 13 is formed on the surface of the silicon wafer 10 to provide a protective effect on the first substrate 11 and/or the circuit structures 12. In an embodiment of the present invention, each circuit structure 12 includes a plurality of first electrical contacts 123 exposed on the surface of the silicon wafer 10 (here also exposed on the first passivation layer 13), and each first electrical contact 123 is correspondingly connected to each pixel reading circuit 122 to facilitate the subsequent electrical connection with the optoelectronic element die. The first passivation layer 13 may be made of silicon oxide (SiOx), silicon nitride (SiNx) or aluminum oxide (AlOx).

Step S2: providing a plurality of optoelectronic element dies, each of the optoelectronic element dies including a substrate and an optoelectronic element structure.

As shown in FIGS. 1 to 3, when the silicon wafer 10 is provided in the above step S1, the present invention may provide a plurality of optoelectronic element dies 20 at the same time. Each optoelectronic element die 20 includes a second substrate 21 and an optoelectronic element structure 22. The second substrate 21 is made of an III-V group semiconductor material, e.g., indium phosphide (InP) or gallium antimonide (GaSb), and the optoelectronic element structure 22 is disposed on the second substrate 21. In an embodiment of the present invention, the optoelectronic element structure 22 may include a sensing layer 221 and a plurality of sensing pixels 222 disposed in the sensing layer 221. The sensing layer 221 may be made of an III-V group semiconductor material, e.g., indium gallium arsenide (InGaAs), aluminum gallium indium arsenide (AlGaInAs), indium gallium arsenide phosphide (InGaAsP), indium arsenide phosphide (InAsP), gallium arsenic antimonide (GaAsSb), indium arsenic antimonide (InAsSb), indium gallium arsenide antimonide (InGaAsSb) or aluminum gallium arsenide antimonide (AlGaAsSb). Herein, each optoelectronic element die 20 may be a sensing element with an infrared sensing function.

In addition, in the structure design, a second passivation layer 23 is formed on the surface of each optoelectronic element die 20 to provide a protective effect for the sensing layer 221 and/or the sensing pixels 222. In an embodiment of the present invention, the optoelectronic element structure 22 includes a plurality of second electrical contacts 223 exposed on the surface of the optoelectronic element die 20 (here also exposed on the second passivation layer 23), and each second electrical contact 223 is correspondingly connected to each sensing pixel 222 to facilitate the subsequent electrical connection with the silicon wafer 10. The second passivation layer 23 may be made of silicon oxide (SiOx), silicon nitride (SiNx) or aluminum oxide (AlOx).

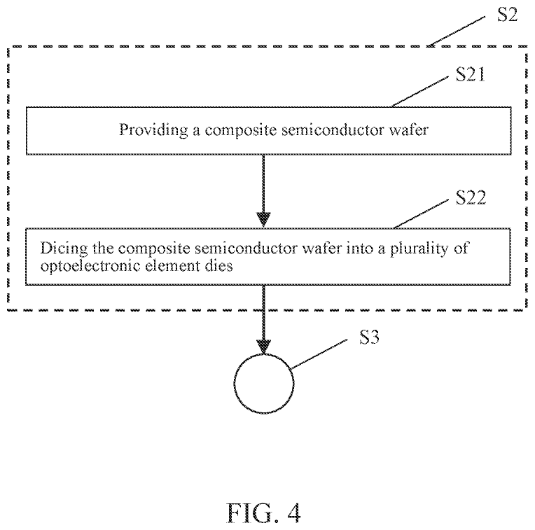

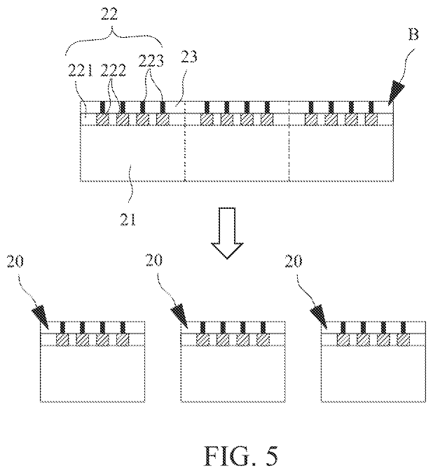

Please refer to FIGS. 4 and 5 together. FIG. 4 is a detailed flowchart of step S2 in the integrating method of optoelectronic elements and circuits of the present invention. FIG. 5 is a schematic view of performing step S2 in the integrating method of optoelectronic elements and circuits of the present invention. As shown in FIG. 4, in an embodiment of the present invention, the step S2 of providing a plurality of optoelectronic element dies further includes the following steps.

Step S21: providing a composite semiconductor wafer.

As shown in FIG. 4 and FIG. 5, the present invention can provide the composite semiconductor wafer B in advance. The composite semiconductor wafer B includes the aforementioned second substrate 21 and optoelectronic element structures 22, and the optoelectronic element structures 22 are disposed on the second substrate 21. Each optoelectronic element structure 22 is located within a pre-divided block range of the second substrate 21 to facilitate the subsequent dicing and shaping of the optoelectronic element die 20. Herein, the composite semiconductor wafer B is a wafer made of an III-V group semiconductor material. A plurality of optoelectronic element dies 20 are used. Each optoelectronic element die 20 includes a second substrate 21 and an optoelectronic element structure 22.

Step S22: dicing the composite semiconductor wafer into a plurality of optoelectronic element dies.

After the composite semiconductor wafer B is provided in the aforementioned step S21, the present invention can perform a dicing process on the composite semiconductor wafer B to dice the composite semiconductor wafer B into the aforementioned optoelectronic element dies 20 according to the pre-divided block range. Each optoelectronic element die 20 formed after dicing will include a part of the second substrate 21 and a single optoelectronic element structure 22 that can independently perform the sensing function.

Step S3: performing a die-to-wafer bonding process such that the optoelectronic element dies are stacked on a surface of the silicon wafer, wherein one of the optoelectronic element dies is correspondingly bonded to one of the circuit structures through the optoelectronic element structure.

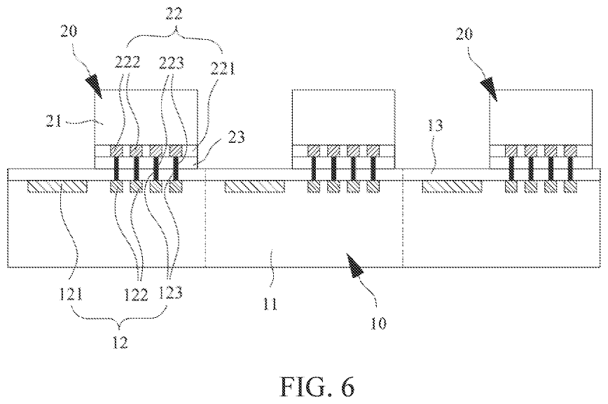

Please refer to FIG. 1 and FIG. 6 together. FIG. 6 is a schematic view of performing step S3 in the integrating method of optoelectronic elements and circuits of the present invention. As shown in FIGS. 1 and 6, after the silicon wafer 10 and the optoelectronic element dies 20 are formed in the aforementioned steps S1 and S2, respectively, the present invention can then perform the die-to-wafer bonding process. The optoelectronic element dies 20 are stacked on the surface of the silicon wafer 10 in a flipped manner. One of the optoelectronic element dies 20 is correspondingly bonded to one of the circuit structures 12 of the silicon wafer 10 through the optoelectronic element structure 22. Meanwhile, each optoelectronic element die 20 is bonded to the first electrical contacts 123 of the corresponding circuit structure 12 exposed on the surface of the silicon wafer 10 through the second electrical contacts 223 exposed on the surface of the optoelectronic element structure 22. As a result, the sensing pixels 222 of the optoelectronic element structure 22 are electrically connected to the pixel reading circuits 122 of the corresponding bonded circuit structure 12.

Step S4: performing a compression over-molding process to encapsulate the optoelectronic element dies and the surface of the silicon wafer with a molding material.

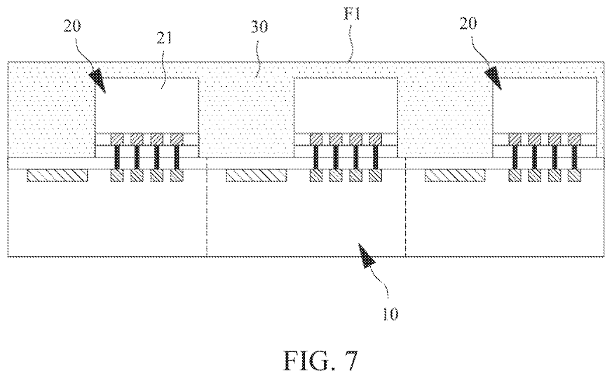

Please refer to FIG. 1 and FIG. 7 together. FIG. 7 is a schematic view of performing step S4 in the integrating method of optoelectronic elements and circuits of the present invention. As shown in FIGS. 1 and 7, after performing the die-to-wafer bonding process in the aforementioned step S3, the present invention can then perform a compression over-molding process on the overall assembly of the optoelectronic element dies 20 and the silicon wafer 10 to encapsulate the optoelectronic element dies 20 and the surface of the silicon wafer 10 with the non-conductive molding material 30. In this step S4, with the surface of the silicon wafer 10 as the baseline, the thickness of the molding material 30 for encapsulation will be greater than the thickness of each optoelectronic element die 20. In other words, the molding material 30 can completely cover each optoelectronic element die 20 (that is, cover the second substrate 21 of each optoelectronic element die 20) and the surface of the silicon wafer 10, and provide an auxiliary fixation effect between each optoelectronic element die 20 and the surface of the silicon wafer 10. At this time, a flat surface to be processed F1 can be formed by the molding material 30 for encapsulation. In an embodiment of the present invention, the molding material 30 includes epoxy resin, phenolic resin or melamine resin, but the present invention is not limited thereto. In addition, the molding material 30 may further be mixed with carbon fiber or glass fiber to increase the structural strength.

Step S5: performing a grinding and polishing process to remove an unnecessary portion of the molding material and an unnecessary portion of the substrate of each of the optoelectronic element dies and expose the substrate of each of the optoelectronic element dies on a top surface after grinding and polishing.

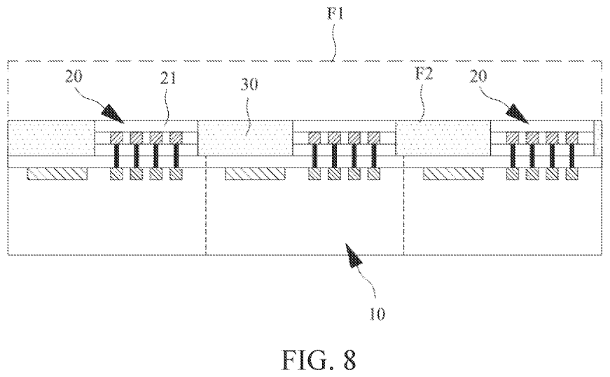

Please refer to FIG. 1, FIG. 7 and FIG. 8 together. FIG. 8 is a schematic view of performing step S5 in the integrating method of optoelectronic elements and circuits of the present invention. As shown in FIGS. 1, 7 and 8, after the compression over-molding process is performed in the aforementioned step S4, the present invention can then perform a grinding and polishing process to the overall assembly of the optoelectronic element dies 20 and the silicon wafer 10 that have been encapsulated with the molding material 30. Starting from the aforementioned surface to be processed F1 formed by the molding material 30, a thinning process is applied to remove the unnecessary portion of the molding material 30 and the unnecessary portion of the second substrate 21 of each optoelectronic element die 20 to form a flat top surface F2 after grinding and polishing. In other words, this process removes a certain thickness of the molding material 30 from the aforementioned surface to be processed F1 and the corresponding thickness of the second substrate 21 of each optoelectronic element die 20. In this step S5, the second substrate 21 of each optoelectronic element die 20 will not be completely removed so that the second substrate 21 of each optoelectronic element die 20 after grinding and polishing still has a remaining thickness, which is approximately between 80 μm and 250 μm, preferably between 100 μm and 200 μm. Therefore, the second substrate 21 of each optoelectronic element die 20 will be exposed on the top surface F of the aforementioned overall assembly after grinding and polishing.

Step S6: performing a dicing process to form a plurality of integrated structures with the optoelectronic elements and the circuits.

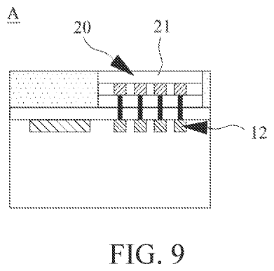

Please refer to FIGS. 1, 8 and 9 together. FIG. 9 is a schematic view of the integrated structure of an optoelectronic element and a circuit of the present invention. As shown in FIGS. 1, 8 and 9, after the grinding and polishing process is performed in the aforementioned step S5, the present invention can then perform a dicing process on the overall assembly of the optoelectronic element dies 20 and the silicon wafer 10 after grinding and polishing in FIG. 8 to form a plurality of integrated structures A with the optoelectronic elements and the circuits (only a single integrated structure A is shown in FIG. 9). In this step S6, the aforementioned overall assembly may be diced according to the pre-divided block range. According to different design requirements, each integrated structure 1 after dicing may have a single optoelectronic element die 20 and a corresponding single circuit structure 12, or having multiple optoelectronic element dies 20 and corresponding multiple circuit structures 12 (e.g., forming a rectangular array of optoelectronic elements (N×N) and a corresponding rectangular array of circuit structures (N×N)).

Accordingly, each integrated structure A after dicing can provide an infrared sensing effect through the optoelectronic element die 20 and the corresponding circuit structure 12. Since the second substrate 21 of the optoelectronic element die 20 is made of an III-V group semiconductor material (e.g., indium phosphide (InP) or gallium antimonide (GaSb)), which has penetrability to infrared light. Therefore, it can be applied to the application with the sensing requirements for wavelengths greater than 1 μm, especially those for wavelengths greater than 1.3 μm. Compared with the conventional infrared sensor for a wavelength of about 940 nm, which easily harms the human eye, the aforementioned integrated structure 1 manufactured by the present invention can reduce the possibility of such harm occurring. Furthermore, the method of the present invention can effectively reduce the possibility of damage between the optoelectronic element die 20 and the circuit structure 12, thereby improving the yield and reliability of integrated structure manufacturing.

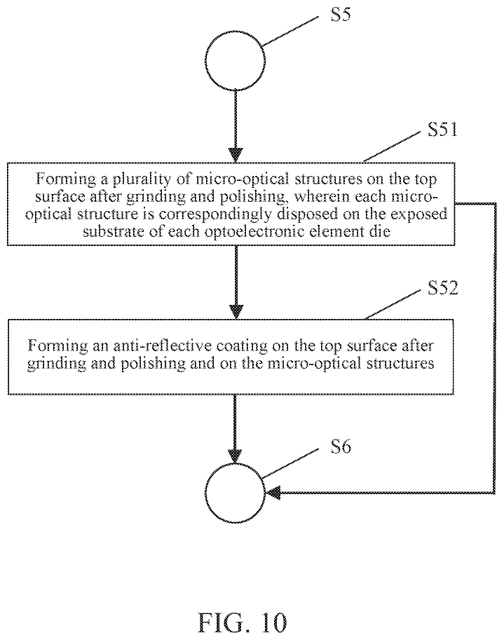

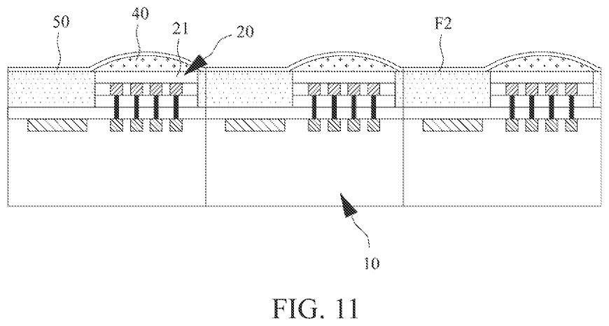

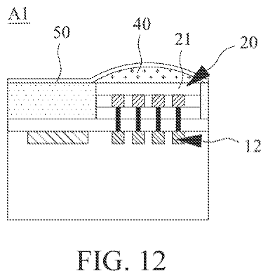

Please refer to FIGS. 10 to 12 below. FIG. 10 is another flowchart of the integrating method of optoelectronic elements and circuits of the present invention. FIG. 11 is another schematic view of the integrated structures of optoelectronic elements and circuits of the present invention. FIG. 12 is another schematic view of the integrated structure of an optoelectronic element and a circuit of the present invention. As shown in FIG. 10, the integrating method of optoelectronic elements and circuits of the present invention further includes the following steps before the aforementioned step S6:

Step S51: forming a plurality of micro-optical structures on the top surface after grinding and polishing, wherein each of the micro-optical structures is correspondingly disposed on the exposed substrate of each of the optoelectronic element dies.

As shown in FIG. 10 and FIG. 11, after performing the grinding and polishing process in the aforementioned step S5, the present invention can first form the micro-optical structures 40 on the top surface F2 of the overall assembly of the optoelectronic element dies 20 and the silicon wafer 10 after grinding and polishing. The micro-optical structures 40 may be made by imprinting using a transparent plastic material, such as poly(methyl methacrylate) (abbreviated as PMMA) or su-8 photoresist, but the present invention is not limited thereto. Each micro-optical structure 40 is correspondingly disposed on the exposed second substrate 21 of each optoelectronic element die 20. In an embodiment of the present invention, each micro-optical structure 40 is a microlens, but the present invention is not limited thereto. Since infrared rays mainly pass through the second substrate 21 of each optoelectronic element die 20 and enter the element and are sensed using the corresponding circuit structure 12, the micro-optical structure 40 can increase the incident intensity and amount of infrared rays passing through the second substrate 21 to improve the sensing effect of infrared rays.

In addition, after the above step S51, a step S52 may also be included: forming an anti-reflective coating on the top surface after grinding and polishing and on the micro-optical structures.

As shown in FIGS. 10 and 11, after the micro-optical structures are formed in the aforementioned step S51, the present invention can then perform a deposition process on the top surface F2 of the aforementioned overall assembly and the micro-optical structures 40, so as to form an anti-reflective coating 50 on the top surface F2 and the micro-optical structures 40. The anti-reflective coating 50 is correspondingly disposed on the exposed second substrate 21 of each optoelectronic element die 20. The anti-reflective coating 50 may be a single-layer coating or a multi-layer coating made of a dielectric material. For example, the anti-reflective coating 50 may include zinc sulfide (ZnS), zinc selenide (ZnSe), germanium (Ge), etc., but the present invention is not limited thereto.

Accordingly, after performing the dicing process in the aforementioned step S6, a plurality of integrated structures A1 having optoelectronic elements and circuits as shown in FIG. 12 can be formed. Since the integrated structure A1 has the micro-optical structure 40 and the anti-reflective coating 50, it can provide a better-infrared sensing effect compared to the aforementioned integrated structure A.

The present invention also includes an integrated structure A or A1 of an optoelectronic element(s) and a circuit(s) manufactured using the integrating method as described above. The structural features of the integrated structure A or A1 of the optoelectronic element(s) and circuit(s) of the present invention are shown in FIG. 9 or FIG. 12, and the forming and integrating methods of the relevant structures have been disclosed in the foregoing description, and will not be repeated here.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made to the function and arrangement of the devices without departing from the scope defined by the claims, including known equivalents and any equivalents that may be anticipated at the time of filing this patent application.

1. An integrating method of optoelectronic elements and circuits, the integrating method comprising the following steps:
providing a silicon wafer, the silicon wafer including a plurality of circuit structures;
providing a plurality of optoelectronic element dies, each of the optoelectronic element dies comprising a substrate and an optoelectronic element structure;
performing a die-to-wafer bonding process such that the optoelectronic element dies are stacked on a surface of the silicon wafer, wherein one of the optoelectronic element dies is correspondingly bonded to one of the circuit structures through the optoelectronic element structure;
performing a compression over-molding process to encapsulate the optoelectronic element dies and the surface of the silicon wafer with a molding material;
performing a grinding and polishing process to remove an unnecessary portion of the molding material and an unnecessary portion of the substrate of each of the optoelectronic element dies and expose the substrate of each of the optoelectronic element dies on a top surface after grinding and polishing; and
performing a dicing process to form a plurality of integrated structures with the optoelectronic elements and the circuits.

2. The integrating method of claim 1, wherein in the step of performing the compression over-molding process, a thickness of the molding material is greater than a thickness of each of the optoelectronic element dies.

3. The integrating method of claim 1, wherein in the step of performing the grinding and polishing process, a remaining thickness of the substrate of each of the optoelectronic element dies is between 80 μm and 250 μm.

4. The integrating method of claim 1, wherein the molding material comprises epoxy resin, phenolic resin or melamine resin.

5. The integrating method of claim 1, wherein the substrate of each of the optoelectronic element dies is made of an III-V group semiconductor material.

6. The integrating method of claim 5, wherein the III-V group semiconductor material comprises indium phosphide or gallium antimonide.

7. The integrating method of claim 1, further comprising the following step:
forming a plurality of micro-optical structures on the top surface after the grinding and polishing process, wherein each of the micro-optical structures is correspondingly disposed on the exposed substrate of each of the optoelectronic element dies.

8. The integrating method of claim 7, further comprising the following step:
forming an anti-reflective coating on the top surface after the grinding and polishing process and on the micro-optical structures.

9. The integrating method of claim 8, wherein the anti-reflective coating comprises zinc sulfide, zinc selenide or germanium.

10. The integrating method of claim 1, wherein the step of providing the optoelectronic element dies further comprises the following steps:
providing a composite semiconductor wafer; and
dicing the composite semiconductor wafer into the optoelectronic element dies.

11. The integrating method of claim 1, wherein each of the circuit structures is a sensing circuit or a control circuit.

12. The integrating method of claim 1, wherein each of the circuit structures comprises a plurality of first electrical contacts exposed on the surface of the silicon wafer, and each of the optoelectronic element structures comprises a plurality of second electrical contacts exposed on a surface of the optoelectronic element structure; and in the die-to-wafer bonding process, each of the optoelectronic element dies is correspondingly connected to the first electrical contacts of each of the circuit structures through the second electrical contacts of the optoelectronic element structure.

13. An integrated structure of an optoelectronic element and a circuit formed using the integrating method of claim 1.
